(19) United States
(12) Patent Application Publication
(10) Pub. No.: US 2025/0329515 A1
(43) Pub. Date: Oct. 23, 2025

(54) FILM FORMING METHOD AND PLASMA PROCESSING APPARATUS

(71) Applicant: Tokyo Electron Limited, Tokyo (JP)

(72) Inventors: Takashi FUSE, Tokyo (JP); Kazuya TODA, Nirasaki-shi (JP); Haruka OKOSHI, Nirasaki-shi, Yamanashi (JP)

(21) Appl. No.: 19/210,017

(22) Filed: May 16, 2025

Related U.S. Application Data
(63) Continuation of application No. PCT/JP2023/040168, filed on Nov. 8, 2023.

(30) Foreign Application Priority Data
Nov. 17, 2022 (JP) 2022-184164

(51) Int. Cl. H01J 37/32

(52) U.S. Cl. CPC H01J 37/3244; H01J 37/32192; H01J 2237/332

(57) ABSTRACT

A method of selectively growing a second insulating film on a first insulating film, includes: providing a substrate including the first insulating film and a metal film; generating a first plasma by supplying a carbon-containing gas, and forming, on the metal film, a graphene film having a first thickness and a carbon nanowall growing from the graphene film, using the first plasma; generating a second plasma by supplying an oxygen-containing gas, and removing a carbon film on the first insulating film, which is formed in the forming of the carbon nanowall, using the second plasma; generating a third plasma by supplying a hydrogen-containing gas, and removing an oxygen defect of the graphene film and the carbon nanowall, using the third plasma; and generating a fourth plasma by supplying a silicon-containing gas, and forming the second insulating film having a second thickness on the first insulating film, using the fourth plasma.

### CROSS-REFERENCE TO RELATED APPLICATIONS

This application is a bypass continuation application of International Application No. PCT/JP2023/040168 having an international filing date of Nov. 8, 2023 and designating the United States, the international application being based upon and claiming the benefit of priority from Japanese Patent Application No. 2022-184164, filed on Nov. 17, 2022, the entire contents of which are incorporated herein by reference.

### TECHNICAL FIELD

The present disclosure relates to a film forming method and a plasma processing apparatus.

### BACKGROUND

Patent Document 1 discloses that, in a state in which a surface of a substrate to be processed has no a catalytic function, a graphene structure is formed on the surface of the substrate to be processed by a remote microwave plasma chemical vapor deposition (CVD) using a carbon-containing gas as a film-forming raw material gas.

### PRIOR ART DOCUMENTS

### Patent Documents

Patent Document 1: Japanese Patent Laid-Open Publication No. 2019-055887

### SUMMARY

According to one embodiment of the present disclosure, a film forming method of selectively growing a second insulating film on a first insulating film, includes: providing a substrate including the first insulating film and a metal film; generating a first plasma by supplying a carbon-containing gas, and forming, on the metal film, a graphene film having a first film thickness and a carbon nanowall which grows from the graphene film, using the first plasma; generating a second plasma by supplying an oxygen-containing gas, and removing a carbon film on the first insulating film, which is formed in the forming of the carbon nanowall, using the second plasma; generating a third plasma by supplying a hydrogen-containing gas, and removing oxygen defects of the graphene film and the carbon nanowall, using the third plasma; and generating a fourth plasma by supplying a silicon-containing gas, and forming the second insulating film having a second film thickness on the first insulating film, using the fourth plasma.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an example of a film forming apparatus according to an embodiment of the present disclosure.

FIG. 2 is a view illustrating an example of lateral growth during a selective film formation.

FIG. 3 is a view illustrating an example of a process of a selective film formation according to this embodiment.

FIG. 4 is a graph showing an example of an experimental result after processing using plasma of an oxygen-containing gas.

FIG. 5 is a graph showing an example of an experimental result according to Reference example.

FIG. 6 is a graph showing an example of an experimental result after processing using plasma of a hydrogen-containing gas.

FIG. 7 is a flowchart showing an example of a film forming method according to an embodiment.

FIG. 8 is a view illustrating an example of an experimental result according to an embodiment.

### DETAILED DESCRIPTION

Hereinafter, embodiments of a film forming method and plasma processing apparatus disclosed herein will be described in detail with reference to the accompanying drawings. In addition, the technology disclosed herein is not limited to the following embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a selective film formation in the related art, a method of selecting a film forming region by selectively attaching a film forming inhibitor such as a self-assembled monolayer (SAM) is used. However, selectivity may be lost due to a low density of the film forming inhibitor. Further, when graphene is used as the film forming inhibitor, it is difficult to thicken the graphene due to a film forming rate. Therefore, when a film thickness of a selectively grown insulating film exceeds a film thickness of the graphene, the insulating film may be laterally grown above the graphene from the film forming region. Accordingly, it is necessary to suppress loss of selectivity due to such a lateral growth of the insulating film in the selective film formation.

### Configuration of Film Forming Apparatus 1

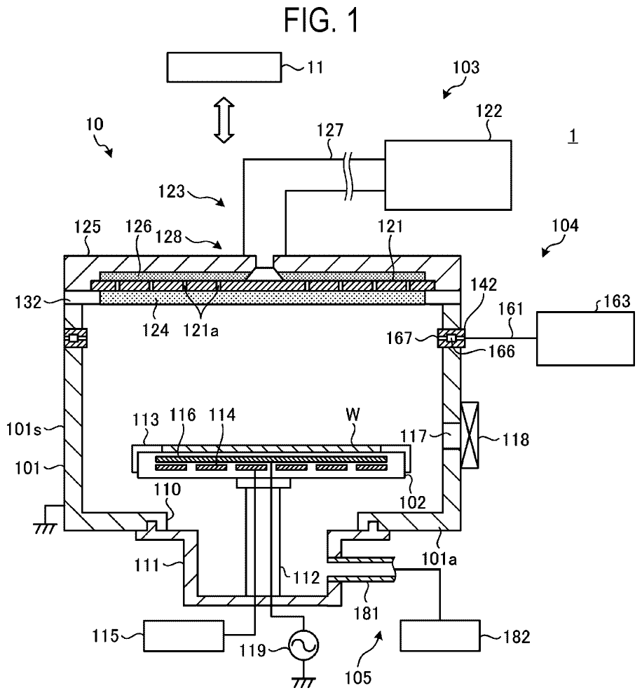

FIG. 1 is a schematic cross-sectional view illustrating an example of a film forming apparatus according to an embodiment of the present disclosure. A film forming apparatus 1 illustrated in FIG. 1 is configured as, for example, an RLSA (registered trademark) microwave plasma type plasma processing apparatus. Further, the film forming apparatus 1 is an example of a plasma processing apparatus.

The film forming apparatus 1 includes an apparatus main body 10 and a controller 11 that controls the apparatus main body 10. The apparatus main body 10 includes a chamber 101, a stage 102, a microwave introduction mechanism 103, a gas supply mechanism 104, and an exhaust mechanism 105.

The chamber 101 is formed in a substantially cylindrical shape. An opening 110 is formed in a substantially central portion of a bottom wall 101a of the chamber 101. The bottom wall 101a is provided with an exhaust chamber 111 that communicates with the opening 101 and protrudes downward. An opening 117 through which a substrate (hereinafter, also referred to as a wafer) W passes is formed in a sidewall 101s of the chamber 101. The opening 117 is open and closed by a gate valve 118. Further, chamber 101 is an example of a processing container.

The substrate W to be processed is placed on the stage 102. The stage 102 has a substantially disk shape, and is formed of ceramics such as AIN. The stage 102 is supported by a cylindrical support member 112 that extends upward from a substantially center of a bottom portion of the exhaust chamber 111 and is formed of ceramics such as AIN. At an outer edge of the stage 102, an edge ring 113 is provided to surround the substrate W placed on the stage 102. Further, lifting pins (not illustrated) for raising and lowering the substrate W is provided inside the stage 102 to be able to move upward and downward with respect to an upper surface of the stage 102.

Further, a resistance heater 114 is embedded in the stage 102. The heater 114 heats the substrate W placed on the stage 102 by being supplied with power from a heater power supply 115. Further, a thermocouple (not illustrated) is inserted into the stage 102. A temperature of the substrate W may be controlled to, for example, 350 degrees C. to 850 degrees C., based on a signal from the thermocouple. Further, an electrode 116 having approximately the same size as the wafer W is embedded in the stage 102 above the heater 114. A bias power supply 119 is electrically connected to the electrode 116. The bias power supply 119 supplies bias power of a preset frequency and a preset magnitude to the electrode 116. By the bias power supplied to the electrode, ions are drawn into the substrate W placed on the stage 102. Further, the bias power supply 119 may not be provided depending on characteristics of a plasma processing.

The microwave introduction mechanism 103 is provided above the chamber 101, and includes an antenna 121, a microwave outputter 122, and a microwave transmission mechanism 123. A plurality of slots 121a similar to through-holes are formed in the antenna 121. The microwave outputter 122 outputs microwaves. The microwave transmission mechanism 123 induces the microwaves output from the microwave outputter 122 to the antenna 121.

A dielectric window 124 formed of a dielectric material is provided below the antenna 121. The dielectric window 124 is supported by a support member 132 provided in a ring shape at an upper portion of the chamber 101. A slow-wave plate 126 is provided on the antenna 121. A shield member 126 is provided over the antenna 121. A flow path (not illustrated) is provided inside the shield member 125. The shield member 125 cools the antenna 121, the dielectric window 124, and the slow-wave plate 126, using a fluid such as water, which flows in the flow path.

The antenna 121 is formed of, for example, a copper plate, an aluminum plate or the like, which has a surface plated with silver or gold. The plurality of slots 121a for radiating the microwaves are arranged in a preset pattern. The arrangement pattern of the slots 121a is appropriately set such that the microwaves are evenly radiated. A suitable example of the pattern may include a radial line slot pattern in which a plurality of pairs of slots 121a, each pair including two slots 121a arranged in a T-shape, are concentrically arranged. A length or arrangement interval of the slots 121a are appropriately determined according to an effective wavelength (λg) of microwaves. Further, the slot 121a may have other shapes such as a circular shape and an arc shape. Further, the arrangement form of the slots 121a is not particularly limited. The slots 121a may be arranged, for example, in a spiral shape or a radial shape, in addition to a concentric shape. The pattern of the slots 121a is appropriately set so as to achieve microwave radiation characteristics by which a desired plasma density distribution is obtained.

The slow-wave plate 126 is formed of a dielectric having a dielectric constant larger than a vacuum, such as quartz, ceramics (Al₂O₃), polytetrafluoroethylene or polyimide. The slow-wave plate 126 has a function of making a wavelength of microwaves shorter than that in the vacuum, thus reducing the size of the antenna 121. In addition, the dielectric window 124 is similarly made of a dielectric.

Thicknesses of the dielectric window 124 and the slow-wave plate 126 are adjusted such that an equivalent circuit formed by the slow-wave plate 126, the antenna 121, the dielectric window 124, and the plasma satisfies resonance conditions. By adjusting the thickness of the slow-wave plate 126, a phase of microwaves may be adjusted. By adjusting the thickness of the slow-wave plate 126 such that a junction of the antenna 121 becomes an “antinode” of a standing wave, reflection of the microwaves is minimized. This maximizes radiation energy of the microwaves. Further, the slow-wave plate 126 and the dielectric window 124 are made of the same material. This makes it possible to prevent interfacial reflection of the microwaves.

The microwave outputter 122 includes a microwave oscillator. The microwave oscillator may be of a magnetron type or a solid state type. A frequency of microwaves generated by the microwave oscillator may be in a range of, for example, 300 MHz to 10 GHz. As an example, the microwave outputter 122 outputs the microwaves with a frequency of 2.45 GHz, using the magnetron-type microwave oscillator. The microwaves are an example of electromagnetic waves.

The microwave transmission mechanism 123 includes a waveguide 127 and a coaxial waveguide 128. Further, the microwave transmission mechanism 123 may include a mode conversion mechanism. The waveguide 127 guides the microwaves output from the microwave outputter 122. The coaxial waveguide 128 includes an inner conductor connected to a center of the antenna 121 and an outer conductor provided outside the inner conductor. The mode conversion mechanism is provided between the waveguide 127 and the coaxial waveguide 128. The microwaves output from the microwave outputter 122 propagate in the waveguide 127 in a TE mode. A mode of the microwaves is converted from the TE mode to a TEM mode by the mode conversion mechanism. The microwaves, the mode of which is converted to the TEM mode, propagate to the slow-wave plate 126 via the coaxial waveguide 128, and are radiated into the chamber 101 from the slow-wave plate 126 via the slots 121a of the antenna 121 and the dielectric window 124. In addition, a tuner (not illustrated) for matching impedance of load (plasma) in the chamber 101 with output impedance of the microwave outputter 122 is provided in the waveguide 127.

The gas supply mechanism 104 includes a shower ring 142 provided in a ring shape along an inner wall of the chamber 101. The shower ring 142 includes a ring-shaped flow path 166 provided therein and a plurality of discharge ports 167 connected to the flow path 166 to be open inward of the flow path 166. A gas supply 163 is connected to the flow path 166 via a pipe 161. The gas supply 163 is provided with a plurality of gas sources and a plurality of flow rate controllers. In an embodiment, the gas supply 163 is configured to supply at least one processing gas to the shower ring 142 from a corresponding gas source via a corresponding flow rate controller. The gas supplied to the shower ring 142 is supplied into the chamber 101 via the plurality of discharge ports 167.

In addition, in a case in which a graphene film is formed on the substrate W, the gas supply 163 supplies a carbon-containing gas, a hydrogen-containing gas, and a rare gas (noble gas), flow rates of which are controlled to preset flow rates, into the chamber 101 via the shower ring 142. Further, in this embodiment, instead of the graphene film, a carbon nanowall including the graphene film is formed on a metal film in the substrate W, and a carbon film is formed on a first insulating film. In this embodiment, the carbon-containing gas is, for example, an acetylene (C₂H₂) gas. In addition to the C₂H₂ gas, any one of an ethylene (C₂H₄) gas, a methane (CH₄) gas, an ethane (C₂H₆) gas, a propane (C₃H₈) gas, a propylene (C₃H₆) gas, a methanol (CH₃OH) gas, and an ethanol (C₂H₅OH) gas may be used. Further, in this embodiment, the hydrogen-containing gas is, for example, a hydrogen gas. Instead of the hydrogen gas or in addition to the hydrogen gas, a halogen-based gas such as a F₂ (fluorine) gas, a Cl₂ (chlorine) gas, or a Br₂ (bromine) gas may be used. Further, in this embodiment, the rare gas is, for example, an Ar gas. Instead of the Ar gas, another rare gas such as a He gas may be used.

In addition, in a case in which the carbon film formed on the first insulating film in the substrate W is etched (removed), the gas supply 163 supplies an oxygen-containing gas and a rare gas, flow rates of which are controlled to preset flow rates, into the chamber 101 via the shower ring 142. Further, in a case in which the carbon nanowall including the graphene film is modified, the gas supply 163 supplies a hydrogen-containing gas and a rare gas, flow rates of which are controlled to preset flow rates, into the chamber 101 via the shower ring 142. Further, in a case in which a second insulating film is formed on the first insulating film, the gas supply 163 supplies a silicon-containing gas and a rare gas, flow rates of which are controlled to preset flow rates, into the chamber 101 via the shower ring 142. In this embodiment, the oxygen-containing gas is, for example, an oxygen gas. Further, the silicon-containing gas is, for example, a monosilane gas.

The exhaust mechanism 105 includes the exhaust chamber 111, an exhaust pipe 181 provided in a sidewall of the exhaust chamber 111, and an exhaust device 182 connected to the exhaust pipe 181. The exhaust device 182 includes a vacuum pump, a pressure control value, and the like.

The controller 11 includes a memory, a processor, and an input/output interface. The memory stores programs executed by the processor and recipes including conditions for each process. The processor executes a program read from the memory, and controls individual constituent elements of the apparatus main body 10 using the input/output interface, based on the recipes stored in the memory.

For example, the controller 11 controls individual constituent elements of the film forming apparatus 1 to execute a film forming method which will be described later. As a specific example, the controller 11 performs an operation of loading and providing the substrate W including the first insulating film and the metal film into the chamber 101. The controller 11 performs an operation of supplying the carbon-containing gas into the chamber 101 to generate plasma, and forming, on the metal film, the graphene film having a first film thickness and a carbon nanowall which grows from the graphene film, using the generated plasma. The controller 11 performs an operation of supplying the oxygen-containing gas into the chamber 101 to generate plasma, and removing a carbon film on the first insulating film, using the generated plasma. The controller 11 performs an operation of supplying the hydrogen-containing gas into the chamber 101 to generate plasma, and removing an oxygen defect of the graphene film and the carbon nanowall, using the generated plasma. The controller 11 performs an operation of supplying the silicon-containing gas into the chamber 101 to generate plasma, and forming the second insulating film having a second film thickness on the first insulating film, using the generated plasma. Here, as the carbon-containing gas, the acetylene (C₂H₂) gas supplied from the gas supply 163 may be used. The carbon-containing gas is not limited to the acetylene gas. For example, any one of an ethylene (C₂H₄) gas, a methane (CH₄) gas, an ethane (C₂H₆) gas, a propane (C₃H₈) gas, a propylene (C₃H₆) gas, a methanol (CH₃OH) gas, and an ethanol (C₂H₅OH) gas may be used. Further, as the silicon-containing gas, the monosilane gas supplied from the gas supply 163 may be used. The silicon-containing gas is not limited to the monosilane gas. For example, another silane-based gas, a silanol gas, or the like may be used.

### Lateral Growth

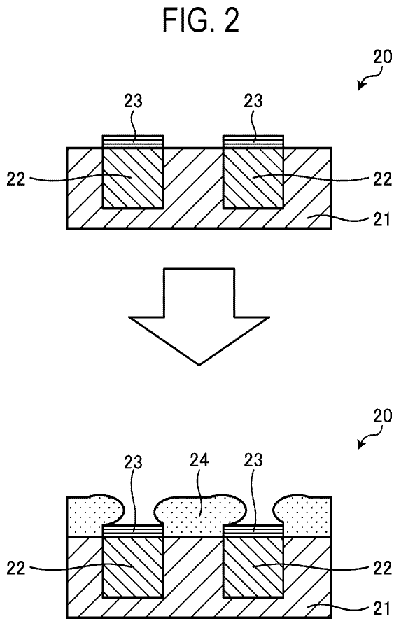

Next, the lateral growth which is problematic in the selective film formation will be described with reference to FIG. 2. FIG. 2 is a view illustrating an example of the lateral growth in the selective film formation. A substrate 20 shown in FIG. 2 includes a first insulating film 21, a metal film 22, and a graphene film 23. A case where, in the substrate 20, a second insulating film 24 is formed on the first insulating film 21 using the graphene film 23 as a mask, is considered. In this case, it is difficult to thicken the graphene film 23 since the graphene film is made of a two-dimensional material. Therefore, the second insulating film 24 formed on the first insulating film 21 laterally grows on the graphene film 23. In this embodiment, instead of the graphene film 23, the carbon nanowall including the graphene film is formed on the metal film 22 to suppress the lateral growth.

### Selective Film Formation by Carbon Nanowall

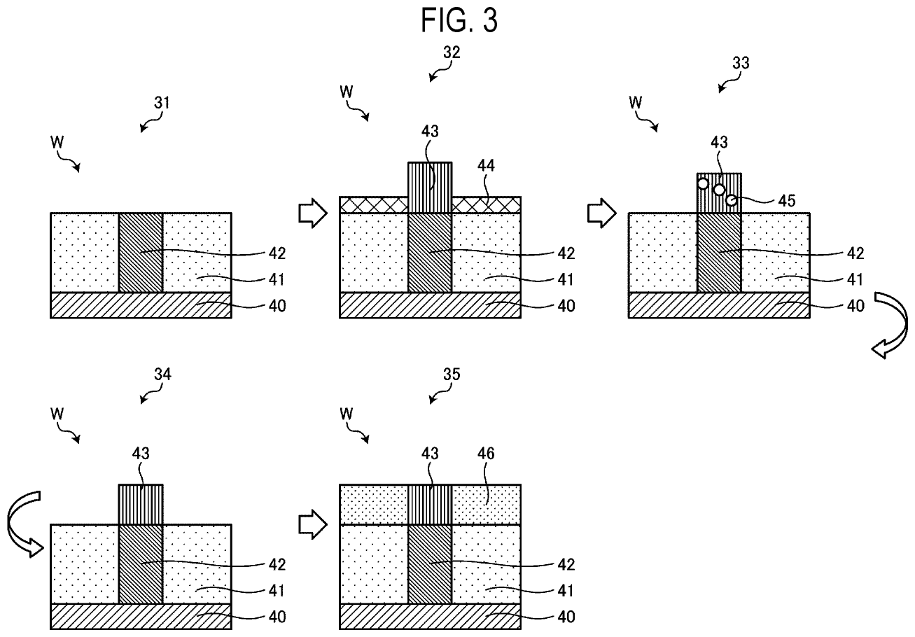

Next, the selective film formation by the carbon nanowall will be described with reference to FIG. 3. FIG. 3 is a view illustrating an example of an operation of the selective film formation according to this embodiment. As illustrated in FIG. 3, in this embodiment, the selective film formation is performed in a sequence of States 31 to 35. State 31 is a state in which the substrate W is loaded into the chamber 101. The substrate W is formed such that a first insulating film 41 and a metal film 42 are arranged horizontally on a silicon substrate 40. That is, in a surface of the substrate W, a portion at which the first insulating film 41 is exposed and a portion at which the metal film 42 is exposed exist. Further, the silicon substrate 40 may be made of, for example, silicon or silicon oxide. Further, the first insulating film 41 may include, for example, a silicon oxide film such as SiO₂, an aluminum oxide film such as AlOₓ, a Low-k film such as SiOC, and the like. Further, the metal film 42 may be, for example, a metal film such as ruthenium (Ru), cobalt (Co) or copper (Cu), or a metal-containing film containing such a metal. Further, the metal film 42 may be one capped with graphene.

State 32 is a state after the carbon nanowall including the graphene film is grown on the substrate W in State 31. In State 32, a carbon nanowall 43 is formed on the metal film 42. Further, since the carbon nanowall 43 is grown from the graphene film, the graphene film exists under the carbon nanowall 43. However, in FIG. 3, the carbon nanowall 43 is shown without distinguishing the carbon nanowall 43 and the graphene film from each other. In the following, the carbon nanowall 43 will be described to include the graphene film. Further, a carbon film 44 is formed on the first insulating film 41. The carbon film 44 includes, for example, amorphous carbon and the like. The carbon nanowall 43 has a film thickness of about 10 nm to about 20 nm. The carbon film 44 has a film thickness of about several nm.

State 33 is a state after the carbon film 44 on the first insulating film 41 is removed from the substrate W in State 32 by etching using plasma of the oxygen-containing gas. State 33 is a state in which a surface of the first insulating film 41 is exposed as the carbon film 44 on the first insulating film 41 is removed. Further, a surface of the carbon nanowall 43 on the metal film 42 is slightly etched when etching the carbon film 44. The remaining film thickness of the carbon nanowall 43 may be about 10 nm. Further, oxygen defects 45 occur in the carbon nanowall 43.

When a second insulating film 46 is formed on the first insulating film 41, the insulating film may be grown starting from the oxygen defects 45 in the carbon nanowall 43. Therefore, in order to remove the oxygen defects 45, the carbon nanowall 43 may be modified using the plasma of the oxygen-containing gas.

State 34 is a state after the oxygen defects 45 in the carbon nanowall 43 are reduced in and removed from the substrate W in State 33 using plasma of the hydrogen-containing gas. In State 34, the surface of the first insulating film 41 is exposed, and the oxygen defect 45 is removed from the carbon nanowall 43.

State 35 is a state after the second insulating film 46 is formed on the first insulating film 41 of the substrate W in State 34 using plasma of the silicon-containing gas. In State 35, an upper portion of the metal film 42 is covered with the carbon nanowall 43. Thus, the second insulating film 46 is not formed on the metal film 42. At this time, the graphene film included in the carbon nanowall 43 also acts as an inhibitor and plays a role in the selective growth. Meanwhile, the second insulating film 46 is formed on the first insulating film 41. That is, in State 35, the second insulating film 46 is selectively grown (selectively formed) on the first insulating film 41. In other words, in State 35, the second insulating film 46 is formed using, as a mask, the graphene film and the carbon nanowall 43. At this time, a film thickness of the second insulating film 46 is about 10 nm, and a film thickness of the carbon nanowall 43 is also about 10 nm. This makes it possible to suppress the second insulating film 46 from being formed in the lateral direction. That is, the film thickness (second film thickness) of the second insulating film 46 is equal to or smaller than the film thickness (first film thickness) of the first insulating film 41. Further, the second insulating film 46 may be, for example, a silicon oxide film such as SiO₂. Further, the second insulating film 46 may be, for example, an aluminum oxide film such as AlOₓ, which is formed by using plasma of an aluminum-containing gas, or a Low-k film such as SiOC, which is formed by using the plasma of the silicon- and carbon-containing gas.

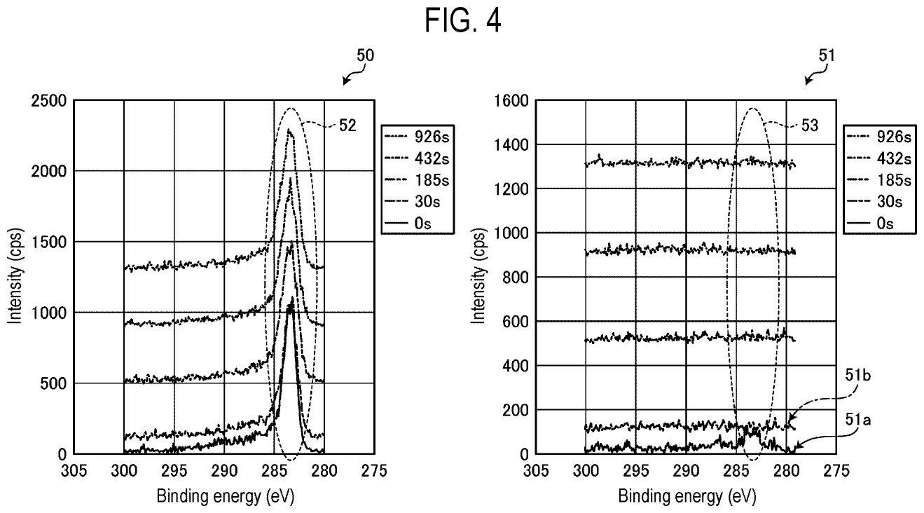

Next, results of an X-ray photoelectron spectroscopy (XPS) performed in State 33, Reference example in which the second insulating film 46 is formed without performing the modification based on the hydrogen-containing gas in State 33, and State 35 will be described with reference to FIGS. 4 to 6. Further, in FIGS. 4 to 6, data of the XPS was obtained in a depth direction while sputtering the surface of the substrate W.

FIG. 4 is a graph showing an example of an experimental result after processing using the plasma of the oxygen-containing gas. Graph 50 shown in FIG. 4 is a result of the XPS at a position at which the metal film 42 and the carbon nanowall 43 in State 33 are formed. Graph 51 is a result of the XPS at a position at which the first insulating film 41 in State 33 is formed. Region 52 in Graph 50 is a region representing signals of carbon, where carbon was detected in the entire graph during a sputtering processing time of 0 sec to 926 sec. That is, in State 33, it can be seen that the carbon nanowall 43 formed on the metal film 42 remains. Meanwhile, in Graph 51, carbon was slightly detected in Graph 51a during the sputtering processing time of 0 sec, but no carbon was detected in Graph 51b during the sputtering processing time of 30 sec. That is, in State 33, it may be considered that the carbon film 44 on the first insulating film 41 is removed.

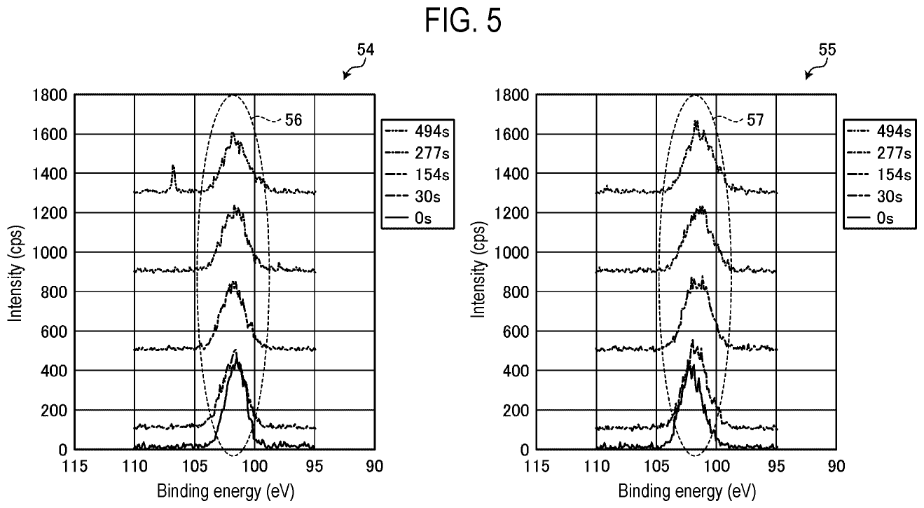

FIG. 5 is a graph showing an example of an experimental result according to Reference example. Graph 54 shown in FIG. 5 is a result of the XPS at a position at which the metal film 42 and the carbon nanowall 43 are formed when a silicon oxide film as the second insulating film 46 is formed without performing the modification using the hydrogen-containing gas in State 33. Further, Graph 55 is a result of the XPS at a position at which the first insulating film 41 is formed in this case. Region 56 of the graph 54 is a region representing signals of silicon, where silicon was detected in the entire graph during the sputtering processing time of 0 sec to 494 sec. That is, it can be seen that the silicon oxide film is formed on the carbon nanowall 43. Region 57 in Graph 55 is a region representing signals of silicon, where silicon was detected in the entire graph during the sputtering processing time of 0 sec to 494 sec. That is, it can be seen that the silicon oxide film is formed on the first insulating film 41 and in Reference example, it can be seen that a blocking property of the carbon nanowall 43 is lost.

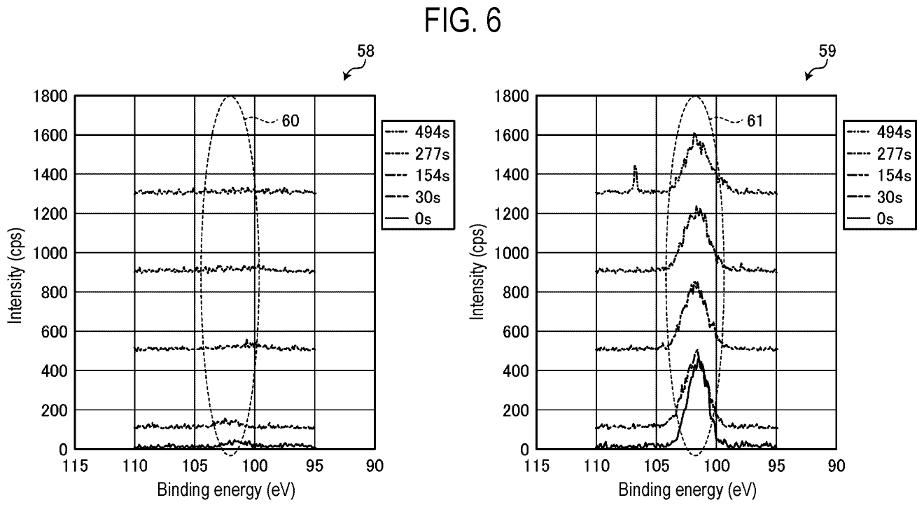

FIG. 6 is a graph showing an example of an experimental result after processing using the plasma of the hydrogen-containing gas. Graph 58 shown in FIG. 6 is a result of the XPS at a position at which the metal film 42 and the carbon nanowall 43 in State 35 are formed. Graph 59 is a result of the XPS at a position at which the first insulating film 41 and the second insulating film 46 in State 35 are formed. Region 60 in Graph 58 is a region representing signals of silicon, where no silicon was detected in the entire graph during the sputtering processing time of 0 sec to 494 sec. That is, it is shown that the silicon oxide film is not formed on the carbon nanowall. Meanwhile, Region 61 in Graph 59 is a region representing signals of silicon, where silicon was detected in the entire graph during the sputtering processing time of 0 sec to 494 sec. That is, it can be seen that the silicon oxide film as the second insulating film 46 is formed on the first insulating film 41 and in State 35, it can be seen that the blocking property of the carbon nanowall 43 is kept so that the second insulating film 46 is selectively formed (selectively grown) on the first insulating film 41.

### Film Forming Method

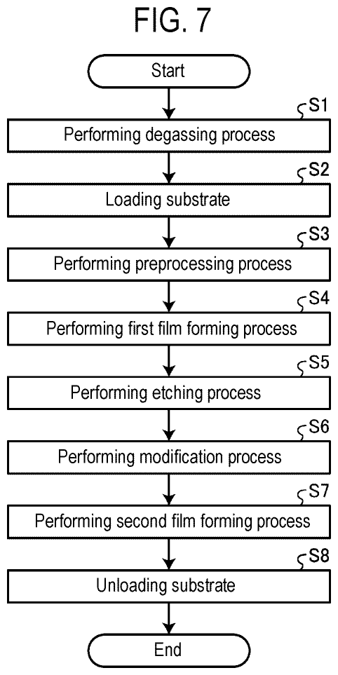

Next, the film forming method according to this embodiment will be described. FIG. 7 is a flowchart showing an example of the film forming method according to this embodiment.

The controller 11 of the film forming apparatus 1 performs a degassing process of removing residual oxygen in a state in which the interior of the chamber 101 is cleaned (Operation S1). The controller 11 controls the gate valve 118 to open the opening 117. When the opening 117 is open, a dummy wafer is loaded into a processing space of the chamber 101 via the opening 117 and is placed on the stage 102. The controller 11 controls the gate valve 118 to close the opening 117.

The controller 11 controls the gas supply 163 to supply the hydrogen-containing gas into the chamber 101 via the plurality of discharge ports 167. Further, the controller 11 controls the exhaust mechanism 105 to control an internal pressure of the chamber 101 to a predetermined pressure (e.g., 50 mTorr to 1 Torr (6.67 Pa to 133 Pa)). The hydrogen-containing gas or the nitrogen-containing gas used in the degassing process may be a H₂ gas or a N₂ gas, a mixed gas of the H₂ gas and the N₂ gas, or a mixed gas of the H₂ gas, the N₂ gas and an Ar gas. The controller 11 controls the microwave introduction mechanism 103 to ignite plasma. The controller 11 executes the degassing process using the plasma of the hydrogen-containing gas or the nitrogen-containing gas for a predetermined period of time (e.g., 120 sec to 600 sec). In the degassing process, an oxidation component such as O₂ or H₂O, which remains in the chamber 101, is discharged as an O-containing radical. Further, in the degassing process, the dummy wafer may not be used. Further, the degassing process may be omitted.

After the degassing process is completed, the controller 11 controls the gate valve 118 to open the opening 117. When the opening 117 is open, the substrate W including the first insulating film 41 and the metal film 42 is loaded into the processing space of the chamber 101 via the opening 117 and is placed on the stage 102. That is, the controller 11 controls the apparatus main body 10 to load the substrate W including the first insulating film 41 and the metal film 42 into the chamber 101 (Operation S2). The controller 11 controls the gate valve 118 to close the opening 117. In addition, Operation S2 is an example of an operation of providing the substrate W including the first insulating film 41 and the metal film 42.

The controller 11 controls the exhaust mechanism 105 to depressurize the internal pressure of the chamber 101 to a predetermined pressure (e.g., 50 mTorr to 1 Torr). The controller 11 controls the gas supply 163 to supply the hydrogen-containing gas and the carbon-containing gas, which are plasma generation gases, to the chamber 101 via the discharge ports 167. The hydrogen-containing gas is a gas including a hydrogen (H₂) gas and an inert gas (Ar gas). The carbon-containing gas is a gas including a hydrocarbon gas (e.g., the C₂H₂ gas) expressed as CₓH_{y} (x and y are natural numbers). Further, the controller 11 controls the microwave introduction mechanism 103 to ignite plasma using microwaves with predetermined power (e.g., 100 W to 1500 W). The controller 11 executes a preprocessing process for improving several characteristics of the surface of the metal film 42 with plasma of the hydrogen-containing gas and the carbon-containing gas for a predetermined period of time (e.g., 5 sec to 15 min) (Operation S3). For example, in the preprocessing process, a close contact between the metal film 42 and the carbon nanowall 43 is improved.

Further, as the plasma generation gas, one or more gases of the H₂ gas, the CₓH_{y} gas, and the Ar gas may be used. In the preprocessing process, the film formation of the carbon nanowall is not performed even when the CₓH_{y} gas is supplied. In the preprocessing process, an anneal processing may be performed in addition to or instead of the plasma processing. When the anneal processing is performed, the internal pressure of the chamber 101 is depressurized to a predetermined pressure (e.g., 50 mTorr to 1 Torr) so that, for example, the hydrogen-containing gas is supplied into the chamber 101. Further, the preprocessing process may be omitted.

After the preprocessing process is completed, the controller 11 stops the generation of plasma by stopping the output of the microwaves. The controller 11 controls the exhaust mechanism 105 to depressurize the internal pressure of the chamber 101 to a predetermined pressure (e.g., 1 mTorr to 1 Torr (0.133 Pa to 133 Pa). Further, the predetermined pressure may be in a range of 10 mTorr to 100 mTorr (1.33 Pa to 13.3 Pa). The controller 11 controls the heater power supply 115 to heat the substrate W at a predetermined temperature (e.g., 300 degrees C. to 500 degrees C.). The controller 11 controls the gas supply 163 to supply the hydrogen-containing gas and the carbon-containing gas, which are plasma generation gases, to the chamber 101 via the discharge ports 167. The hydrogen-containing gas is a gas including the hydrogen (H₂) gas and the inert gas (Ar gas). As the plasma generation gas, the inert gas may be used instead of the hydrogen-containing gas. The carbon-containing gas is, for example, the C₂H₂ gas or a C₂H₄ gas. Further, the controller 11 controls the microwave introduction mechanism 103 to ignite plasma with predetermined power (e.g., 300 W to 1500 W). The controller 11 executes a first film forming process of forming, on the metal film 42, the graphene film having the first film thickness (e.g., 10 nm to 20 nm) and the carbon nanowall 43 grown from the graphene film, using plasma of the hydrogen-containing gas and the carbon-containing gas, for a predetermined period of time (e.g., 5 sec to 15 min) (Operation S4). That is, the graphene film is formed under the carbon nanowall 43.

After the first film forming process is completed, the controller 11 stops the generation of plasma by stopping the output of the microwaves. The controller 11 controls the exhaust mechanism 105 to depressurize the internal pressure of the chamber 101 to a predetermined pressure (e.g., 1 mTorr to 1 Torr (0.133 Pa to 133 Pa)). The controller 11 controls the heater power supply 115 to heat the substrate W at a predetermined temperature (e.g., 300 degrees C. to 500 degrees C.). The controller 11 controls the gas supply 163 to supply the oxygen-containing gas, which is a plasma generation gas, to the chamber 101 via the discharge ports 167. The oxygen-containing gas is a gas including the oxygen (O₂) gas and the inert gas (the Ar gas). Further, controller 11 controls the microwave introduction mechanism 103 to ignite plasma with predetermined power (e.g., 300 W to 1500 W). The controller 11 executes an etching process of removing the carbon film 44 on the first insulating film 41 with plasma of the oxygen-containing gas for a predetermined period of time (e.g., 5 sec to 15 min) (Operation S5).

After the etching process is completed, the controller 11 stops the generation of plasma by stopping the output of the microwaves. The controller 11 controls the exhaust mechanism 105 to depressurize the internal pressure of the chamber 101 to a predetermined pressure (e.g., 1 mTorr to 1 Torr (0.133 Pa to 133 Pa)). The controller 11 controls the heater power supply 115 to heat the substrate W at a predetermined temperature (e.g., 300 degrees C. to 500 degrees C.). The controller 11 controls the gas supply 163 to supply the hydrogen-containing gas, which is a plasma generation gas, to the chamber 101 via the discharge ports 167. The hydrogen-containing gas is a gas including the hydrogen (H₂) gas and the inert gas (the Ar gas). Further, the controller 11 controls the microwave introduction mechanism 103 to ignite plasma with predetermined power (e.g., 300 W to 1,500 W). The controller 11 executes a modifying process of removing the oxygen defects 45 of the carbon nanowall 43 with plasma of the hydrogen-containing gas for a predetermined period of time (e.g., 5 sec to 15 min) (Operation S6).

After the modifying process is completed, the controller 11 stops the generation of plasma by stopping the output of the microwaves. The controller 11 controls the exhaust mechanism 105 to depressurize the internal pressure of the chamber 101 to a predetermined pressure (e.g., 1 mTorr to 1 Torr (0.133 Pa to 133 Pa)). The controller 11 controls the heater power supply 15 to heat the substrate W at a predetermined temperature (e.g., 300 degrees C. to 500 degrees C.). The controller 11 controls the gas supply 163 to supply a trimethylaluminum (TAM) gas, which is a catalytic gas, to the chamber 101 via the discharge ports 167. The catalytic gas is a gas including the trimethylaluminum gas and the inert gas (the Ar gas). In the substrate W, trimethylaluminum is adsorbed to the first insulating film 41. Further, the controller 11 controls the gas supply 163 to supply a silanol gas to the chamber 101 via the discharge ports 167. The silanol gas is, for example, a gas including a tris(tert-pentoxy)silanol (TPSOL) gas or tris(tert-buthoxy)silanol (TBSOL) gas and the inert gas (the Ar gas). In the substrate W, the TPSOL (TBSOL) is further adsorbed to the trimethylaluminum adsorbed to the first insulating film 41. On the first insulating film 41, the trimethylaluminum functions as a catalyst so that the second insulating film 46 is formed. That is, the controller 11 executes a second film forming process of forming the second insulating film 46 having the second film thickness (e.g., 5 nm to 10 nm) on the first insulating film 41 with the catalytic gas (trimethylaluminum gas) and the silanol gas (Operation S7).

After the second film forming process is completed, the controller 11 controls the gate valve 118 to open the opening 117. The controller 11 controls the apparatus main body 10 to raise the substrate W by moving substrate supporting pins (not illustrated) upward from the upper surface of the stage 102. When the opening 117 is open, the substrate W is unloaded from the interior of the chamber 101 via the opening 117 by an arm provided in a transfer chamber (not illustrated). That is, the controller 11 controls the apparatus main body 10 to unload the substrate W from the interior of the chamber 101 (Operation S8). As described above, after the carbon nanowall 43 is formed, the carbon film 44 is removed to modify the carbon nanowall 43, and then the second insulating film 46 is formed on the first insulating film 41. This makes it possible to suppress loss of selectivity due to the lateral growth of the insulating film in the selective film formation. That is, the second insulating film 46 may be selectively formed on the first insulating film 41.

### Experimental Result

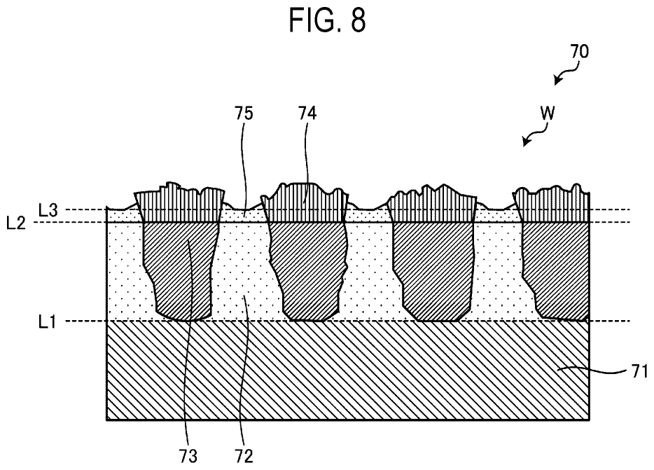

Next, an experimental result according to this embodiment will be described with reference to FIG. 8. FIG. 8 is a view illustrating an example of an experimental result according to this embodiment. Reference numeral 70 in FIG. 8 is a cross-section of a substrate W corresponding to State 35 of FIG. 3. In the substrate W of FIG. 8, a first insulating film 72 and a metal film 73 are formed on a silicon substrate 71. Further, a carbon nanowall 74 including a graphene film is formed on the metal film 73, and a second insulating film 75 is formed on the first insulating film 72. In FIG. 8, line L1 represents lower surfaces of the first insulating film 72 and the metal film 73, and line L2 represents upper surfaces of the first insulating film 72 and the metal film 73. Further, line L3 represents an upper surface of the second insulating film 75. As shown in the cross-section 70, the substrate W, it can be seen that the second insulating film 75 is selectively grown on the first insulating film 72 in the substrate W by the carbon nanowall 74 including the graphene film. Further, it can be seen that the second insulating film 75 is suppressed from laterally growing by the carbon nanowall 74 including the graphene film.

As described above, according to this embodiment, the plasma processing apparatus (the film forming apparatus 1) includes the processing container (the chamber 101) capable of accommodating the substrate W including the first insulating film 41 and the metal film 42, and the controller 11. The controller 11 executes: the operation of loading the substrate W into the processing container; the operation of supplying the carbon-containing gas to generate plasma, and forming, on the metal film 42, the graphene film having the first film thickness and the carbon nanowall which grows from the graphene film, using the generated plasma; the operation of supplying the oxygen-containing gas to generate plasma and removing the carbon film 44 on the first insulating film 41, which is formed in the operation of forming the carbon nanowall, using the generated plasma; the operation of supplying the hydrogen-containing gas to generate plasma and removing the oxygen defects of the graphene film and the carbon nanowall 43, using the generated plasma; and the operation of supplying the silicon-containing gas to generate plasma and forming the second insulating film 46 having the second film thickness on the first insulating film 41, using the generated plasma. As a result, it is possible to suppress loss of selectivity due to the lateral growth of the insulating film in the selective film formation.

Further, according to this embodiment, the metal film 42 includes at least one of Ru, Co, or Cu. As a result, it is possible to form the carbon nanowall 43 on the metal film 42.

Further, according to this embodiment, the first insulating film 41 is any one of the silicon oxide film, the aluminum oxide film, and the Low-k film. As a result, it is possible to selectively form the second insulating film 46 on the first insulating film 41.

Further, according to this embodiment, the second insulating film 46 is any one of the silicon oxide film, the aluminum oxide film, and the Low-k film. As a result, it is possible to selectively form the second insulating film 46 on the first insulating film 41.

Further, according to this embodiment, the carbon-containing gas includes at least one of the C₂H₂ gas, the C₂H₄ gas, the CH₄ gas, the C₂H₆ gas, the C₃Hs gas, the C₃H₆ gas, the CH₃OH gas, or the C₂H₅OH gas. As a result, it is possible to form the carbon nanowall 43 on the metal film 42.

Further, according to this embodiment, the first film thickness is 10 nm or more. As a result, it is possible to suppress the lateral growth of the second insulating film 46.

Further, according to this embodiment, the second film thickness is equal to or smaller than the first film thickness. As a result, it is possible to suppress the lateral growth of the second insulating film 46.

Further, according to this embodiment, in the operation of forming the carbon nanowall 43, the plasma is generated at a pressure in a range of 10 mTorr to 100 mTorr. As a result, it is possible to form the carbon nanowall 43 on the metal film 42.

Further, according to this embodiment, the film forming method selectively grows the second insulating film 46 on the first insulating film 41, and includes: forming the graphene film and the carbon nanowall 43 grown from the graphene film on the metal film 42 in the substrate W including the first insulating film 41 and the metal film 42; and forming the second insulating film 46 on the first insulating film 41 using the graphene film and the carbon nanowall 43 as a mask. As a result, it is possible to suppress loss of selectivity due to the lateral growth of the insulating film in the selective growth (the selective film formation).

According to the present disclosure in some embodiments, it is possible to suppress loss of selectivity due to a lateral growth of an insulating film in a selective film formation.

In addition, the embodiments disclosed herein should be considered to be exemplary and not limitative in all respects. The above embodiments may be omitted, replaced, and modified in various ways without departing from the scope and spirit of the appended claims.

In addition, in the above-described embodiments, the first film forming process, the etching process, the modifying process, and the second film forming process has been described to be executed by the film forming apparatus 1. However, the present disclosure is not limited thereto. For example, the first film forming process, the etching process, the modifying process, and the second film forming process may be executed by an apparatus different from the film forming apparatus 1. In this case, in the second film forming process, the second insulating film 46 may be formed using a thermal atomic layer deposition (ALD) or a plasma enhanced atomic layer deposition (PEALD). For example, in these ALDs, the silicon-containing gas is used as a raw material gas, and the nitrogen-containing gas is used as a reaction gas. The silicon-containing gas is, for example, a gas including a trisilylamine (TSA) gas, a Si—NH₂-based gas, and the like. Further, the silicon-containing gas may be, for example, a gas including a halogen-based raw material such as dichlorosilane (DCS). In addition, in the thermal ALD or the PEALD, the trimethylaluminum (TMA) gas may be supplied as the catalytic gas, and then the silanol gas such as TPSOL or TBSOL may be supplied as the silicon-containing gas. Further, the nitrogen-containing gas is a N₂ gas, a NH₃ gas, gas in which a small amount of a H₂ gas is added to the N₂ gas, or the like.

In addition, in the above-described embodiment, the film forming apparatus 1 that performs various processing such as the etching, the film formation and the like on the substrate W using microwave plasma as a plasma source, has been described as an example, but the disclosed technique is not limited thereto. The plasma source is not limited to the microwave plasma as long as the apparatus performs a processing on the substrate W with plasma. For example, a certain plasma source such as a capacitively coupled plasma, or a magnetron plasma may be used.

In addition, the present disclosure may have the following configurations.

(1) A film forming method of selectively growing a second insulating film on a first insulating film, includes:
providing a substrate including the first insulating film and a metal film;
generating a first plasma by supplying a carbon-containing gas, and forming, on the metal film, a graphene film having a first film thickness and a carbon nanowall which grows from the graphene film, using the first plasma;
generating a second plasma by supplying an oxygen-containing gas, and removing a carbon film on the first insulating film, which is formed in the forming of the carbon nanowall, using the second plasma;
generating a third plasma by supplying a hydrogen-containing gas, and removing oxygen defects of the graphene film and the carbon nanowall, using the third plasma; and
generating a fourth plasma by supplying a silicon-containing gas, and forming the second insulating film having a second film thickness on the first insulating film, using the fourth plasma.

(2) In the film forming method of (1) above, the metal film includes at least one selected from a group consisting of Ru, Co, and Cu.

(3) In the film forming method of (1) or (2) above, the first insulating film is any one of a silicon oxide film, an aluminum oxide film, and a Low-k film.

(4) In the film forming method of any one of (1) to (3) above, the second insulating film is any one of a silicon oxide film, an aluminum oxide film, and a Low-k film.

(5) In the film forming method of any one of (1) to (4) above, the carbon-containing gas includes at least one of a C₂H₂ gas, a C₂H₄ gas, a CH₄ gas, a C₂H₆ gas, a C₃H₈ gas, a C₃H₆ gas, a CH₃OH gas, or a C₂H₅OH gas.

(6) In the film forming method of any one of (1) to (5) above, the first film thickness is 10 nm or more.

(7) In the film forming method of any one of (1) to (6) above, the second film thickness is equal to or smaller than the first film thickness.

(8) In the film forming method of any one of (1) to (7) above, the first plasma generated in the forming the carbon nanowall has a pressure in a range of 10 mTorr to 100 mTorr.

(9) A film forming method of selectively growing a second insulating film on a first insulating film, includes:
forming, on a metal film in a substrate including the first insulating film and the metal film, a graphene film and a carbon nanowall which grows from the graphene film; and
forming the second insulating film on the first insulating film, using, as a mask, the graphene film and the carbon nanowall.

(10) A plasma processing apparatus includes:
a processing container configured to be capable of accommodating a substrate including a first insulating film and a metal film; and
a controller configured to control the plasma processing apparatus to load the substrate into the processing container,
wherein the controller is configured to control the plasma processing apparatus to:
generate a first plasma by supplying a carbon-containing gas, and forming, on the metal film, a graphene film having a first film thickness and a carbon nanowall which grows from the graphene film, using the first plasma;
generate a second plasma by supplying an oxygen-containing gas, and removing a carbon film on the first insulating film, which is formed in the forming of the carbon nanowall, using the second plasma;
generate a third plasma by supplying a hydrogen-containing gas, and removing oxygen defects of the graphene film and the carbon nanowall, using the third plasma; and
generating a fourth plasma by supplying a silicon-containing gas, and forming the second insulating film having a second film thickness on the first insulating film, using the fourth plasma.

What is claimed is:

1. A film forming method of selectively growing a second insulating film on a first insulating film, the film forming method comprising:
providing a substrate including the first insulating film and a metal film;
generating a first plasma by supplying a carbon-containing gas, and forming, on the metal film, a graphene film having a first film thickness and a carbon nanowall which grows from the graphene film, using the first plasma;
generating a second plasma by supplying an oxygen-containing gas, and removing a carbon film on the first insulating film, which is formed in the forming of the carbon nanowall, using the second plasma;
generating a third plasma by supplying a hydrogen-containing gas, and removing oxygen defects of the graphene film and the carbon nanowall, using the third plasma; and
generating a fourth plasma by supplying a silicon-containing gas, and forming the second insulating film having a second film thickness on the first insulating film, using the fourth plasma.

2. The film forming method of claim 1, wherein the metal film includes at least one selected from a group consisting of Ru, Co, and Cu.

3. The film forming method of claim 1, wherein the first insulating film is any one of a silicon oxide film, an aluminum oxide film, and a Low-k film.

4. The film forming method of claim 1, wherein the second insulating film is any one of a silicon oxide film, an aluminum oxide film, and a Low-k film.

5. The film forming method of claim 1, wherein the carbon-containing gas includes at least one of a C₂H₂ gas, a C₂H₄ gas, a CH₄ gas, a C₂H₆ gas, a C₃H₈ gas, a C₃H₆ gas, a CH₃OH gas, or a C₂H₅OH gas.

6. The film forming method of claim 1, wherein the first film thickness is 10 nm or more.

7. The film forming method of claim 1, wherein the second film thickness is equal to or smaller than the first film thickness.

8. The film forming method of claim 1, wherein the first plasma generated in the forming the carbon nanowall has a pressure in a range of 10 mTorr to 100 mTorr.

9. A film forming method of selectively growing a second insulating film on a first insulating film, the film forming method comprising:
forming, on a metal film in a substrate including the first insulating film and the metal film, a graphene film and a carbon nanowall which grows from the graphene film; and
forming the second insulating film on the first insulating film, using, as a mask, the graphene film and the carbon nanowall.

10. A plasma processing apparatus, comprising:
a processing container configured to be capable of accommodating a substrate including a first insulating film and a metal film; and
a controller configured to control the plasma processing apparatus to load the substrate into the processing container,
wherein the controller is configured to control the plasma processing apparatus to:
generate a first plasma by supplying a carbon-containing gas, and forming, on the metal film, a graphene film having a first film thickness and a carbon nanowall which grows from the graphene film, using the first plasma;
generate a second plasma by supplying an oxygen-containing gas, and removing a carbon film on the first insulating film, which is formed in the forming of the carbon nanowall, using the second plasma;
generate a third plasma by supplying a hydrogen-containing gas, and removing oxygen defects of the graphene film and the carbon nanowall, using the third plasma; and
generating a fourth plasma by supplying a silicon-containing gas, and forming the second insulating film having a second film thickness on the first insulating film, using the fourth plasma.
